(19) United States
(12) Patent Application Publication
(10) Pub. No.: US 2009/0193321 A1
(43) Pub. Date: Jul. 30, 2009

(54) VITERBI DECODER AND VITERBI DECODING METHOD

(75) Inventors: Hyun-soo PARK, Seoul (KR); Hui Zhao, Suwon-si (KR)

Correspondence Address: STEIN MCEWEN, LLP, 1400 EYE STREET, NW, SUITE 300, WASHINGTON, DC, 20005, US

(73) Assignee: Samsung Electronics Co., Ltd., Suwon-si (KR)

(21) Appl. No.: 12/146,812

(22) Filed: Jun. 26, 2008

(30) Foreign Application Priority Data
Jan. 29, 2008 (KR) 2008-9086

(51) Int. Cl. H03M 13/23; G06F 11/08

(52) U.S. Cl. 714/795; 714/E11.031

(57) ABSTRACT

A Viterbi decoder and a Viterbi decoding method are provided for simplifying hardware and increasing an operation speed by using a decision feedback unit selecting one of at least two levels based on at least one survivor symbol fed back from a path memory unit. The Viterbi decoder includes a path memory unit (PMU) storing a survivor path, a decision feedback unit (DFU) selecting one of at least two levels based on at least one survivor symbol fed back from the PMU, a branch metric calculation unit (BMCU) calculating a branch metric by using the level selected by the DFU and the received symbol, and an add-compare-selection unit (ACSU) deciding the survivor path by using the branch metric calculated by the BMCU and a previously stored state metric and transmitting the decided survivor path to the PMU.

### CROSS-REFERENCE TO RELATED APPLICATION

This application claims the benefit of Korean Patent Application No. 2008-9086, filed in the Korean Intellectual Property Office on Jan. 29, 2008, the disclosure of which is incorporated herein by reference.

### BACKGROUND OF THE INVENTION

1. Field of the Invention

Aspects of the present invention relate to a Viterbi decoder and a Viterbi decoding method.

2. Description of the Related Art

In general, Viterbi decoders detect optimal binary data based on a statistical characteristic of an input signal. Viterbi decoders detect binary data having fewer errors as optimal binary data of an input signal by defining a level corresponding to a characteristic of the input signal and determining a statistical characteristic of the input signal according to the defined level. Such a Viterbi decoder is called a Viterbi detector.

Viterbi decoders generate levels determined according to a number of taps. For example, a 3-tap Viterbi decoder obtains optimal decoding performance of an input signal by generating maximum 2³ (8) levels. FIGS. 1A and 1B are a general trellis diagram of a 3-tap Viterbi decoder and a syntax obtained by representing the trellis diagram in the C programming language.

The trellis diagram shown in FIG. 1A shows states of VbVc defined from previous states of VaVb and 8 levels available for the case. Referring to FIG. 1A, two previous input signals are represented with 4 cases. If one additional signal (Vc) is input, a state signal is represented with 4 cases by means of a combination of Vb and Vc. All cases, which can be changed from 4 previous states (Va, Vb) to subsequent states (Vb, Vc), are defined as 8 states (or levels) by Va, Vb, and Vc, i.e., 000 (110), 001 (120), 010 (130), 011 (140), 100 (150), 101 (160), 110 (170), and 111 (180).

Referring to FIG. 1B, Viterbi decoding calculates ‘sumnew’ having an error accumulation value of a subsequent state from a variable ‘sum’ having an error accumulation value of a previous state, where ‘sumnew’ is defined with a value obtained by adding a newly generated error value to the error accumulation value of the previous state and selects a smaller one of two sums. For example, if (Vb, Vc) is (0, 0), there exists a case where data is transited from a previous state (0, 0) and a case where data is transited from a previous state (1, 0). A new error value defined in the level 000 (110) is added to the case where data is transited from the previous state (0, 0), a new error value defined in the level 100 (150) is added to the case where data is transited from the previous state (1, 0), and one having a smaller calculation result value of the two is selected. This calculation corresponds to “sumnew[0]=min((sum[0]+abs(inputdata[i]−(int)level[0])),(sum[2]+abs(inputdata[i]−(int)level[4])))” in FIG. 1B. The function ‘min’ is a function of selecting and outputting a smaller one of two elements.

Hardware of the Viterbi decoders is configured to generate and use all levels that can be generated according to the number of taps. Thus, when a Viterbi decoder is applied to devices, such as an optical disc reproducing system with increasing recording density, hardware of the Viterbi decoder can be very complicated since the number of taps increases as recording density increases. As recording density increases, a unit length formed on a disc decreases, and therefore, the intensity of a signal reflected from the disc decreases due to an optical characteristic, and inter-symbol interference (ISI) increases. In order to solve the increasing ISI, the number of taps of a Viterbi decoder is generally increased. Since a Viterbi decoder generates 2^{L} levels when the number of taps is L, if the number of taps increases, the number of levels increases exponentially, and thus, hardware of the Viterbi decoder must be configured to consider all of the exponentially increasing number of levels. Thus, when a Viterbi decoder is applied to devices, such as an optical disc reproducing system with increasing recording density, hardware of the Viterbi decoder is more complicated, and an operation speed is slower.

### SUMMARY OF THE INVENTION

Aspects of the present invention provide a Viterbi decoder and a Viterbi decoding method for simplifying hardware and increasing an operation speed by providing a level used for branch metric calculation using a decision feedback structure.

According to an aspect of the present invention, a Viterbi decoder is provided. The Viterbi decoder comprises a path memory unit (PMU) to store a survivor path; a decision feedback unit (DFU) to select one of at least two levels based on at least one survivor symbol fed back from the PMU; a branch metric calculation unit (BMCU) to calculate a branch metric based on the level selected by the DFU and the received symbol; and an add-compare-selection unit (ACSU) to determine the survivor path based on the branch metric calculated by the BMCU and a previously stored state metric and to transmit the decided survivor path to the PMU.

According to another aspect of the present invention, the number of taps of the Viterbi decoder is L and the number of reduced-taps is K, the number of fed-back survivor symbols is L−K, the DFU comprises 2^{L} levels, L and K are positive integers, and K is smaller than L.

According to another aspect of the present invention, the BMCU performs 2^{K} branch metric calculations.

According to another aspect of the present invention, the at least two levels are previously set levels, the previously set levels comprise a level based on a case where level distribution of the received symbol has asymmetry, and the most significant bit (MSB) of each of the at least two levels is a bit corresponding to the fed-back survivor symbol.

According to another aspect of the present invention, the Viterbi decoder further comprises a level calculation unit (LCU) to calculate the at least two levels and to transmit the calculated level to the DFU, wherein the LCU calculates the levels based on the received symbol and a decoded symbol output from the PMU or based on the received symbol and binary data input from the outside.

According to another aspect of the present invention, the Viterbi decoder further comprises an adaptive equalization unit (AEU) to equalize the received symbol in order to cancel noise from the received symbol and to transmit the equalized symbol to the BMCU, wherein the received symbol of the LCU is an input signal of the AEU.

According to another aspect of the present invention, the Viterbi decoder further comprises a first adaptive equalization unit (AEU) to equalize the received symbol in order to compensate for a frequency characteristic of the received symbol; and a second AEU to equalize an output signal of the first AEU in order to cancel noise from the output signal of the first AEU and to transmit the equalized symbol to the BMCU, wherein the received symbol of the LCU is an input signal of the first AEU.

According to another aspect of the present invention, a Viterbi decoding method is provided. The method comprises selecting at least two levels based on at least one survivor symbol fed back from a path memory; calculating a branch metric based on the selected levels and a received symbol; determining a survivor path based on the calculated branch metric and a previously stored state metric; and storing the determined survivor path.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1A is a general trellis diagram of a 3-tap Viterbi decoder;

FIG. 1B is a syntax obtained by representing the trellis diagram illustrated in FIG. 1A with the C programming language;

FIG. 2 is a functional block diagram of a Viterbi decoder according to an embodiment of the present invention;

FIG. 3 is a detailed block diagram of the Viterbi decoder illustrated in FIG. 2, according to an embodiment of the present invention;

FIG. 4 is a syntax obtained by representing the Viterbi decoder illustrated in FIG. 3 with the C programming language, according to an embodiment of the present invention;

FIG. 5 is another detailed block diagram of the Viterbi decoder illustrated in FIG. 2, according to an embodiment of the present invention;

FIG. 6 is a functional block diagram of a Viterbi decoder according to another embodiment of the present invention;

FIGS. 7A and 7B are a detailed block diagram of the Viterbi decoder illustrated in FIG. 6, according to another embodiment of the present invention;

FIGS. 8A and 8B are another detailed block diagram of the Viterbi decoder illustrated in FIG. 6, according to another embodiment of the present invention;

FIG. 9 is a functional block diagram of a Viterbi decoder according to another embodiment of the present invention;

FIG. 10 is a functional block diagram of a Viterbi decoder according to another embodiment of the present invention; and

FIG. 11 is a flowchart illustrating a Viterbi decoding method according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Aspects of the present invention provide a Viterbi decoder and a Viterbi decoding method to simplify hardware and increase an operation speed using a decision feedback unit selecting one of at least two levels based on at least one survivor symbol fed back from a path memory unit. Aspects of the present invention also provide a Viterbi decoder and a Viterbi decoding method to provide an optimal level even if level distribution of a received symbol is asymmetric, by previously setting the at least two levels. Aspects of the present invention also provide a Viterbi decoder and a Viterbi decoding method to obtain an optimal level even if an amplitude of a received symbol of the Viterbi decoder shakes or is asymmetric, by calculating the at least two levels using one of a decoded symbol output from the path memory unit and binary data input from the outside, and the received symbol of the Viterbi decoder.

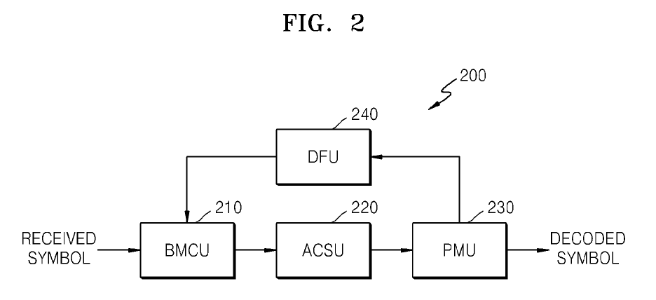

FIG. 2 shows a Viterbi decoder 200 according to an embodiment of the present invention. The Viterbi decoder 200 includes a branch metric calculation unit (BMCU) 210, an add-compare-selection unit (ACSU) 220, a path memory unit (PMU) 230, and a decision feedback unit (DFU) 240. According to other aspects of the present invention, the Viterbi decoder 200 may include additional and/or different units. Similarly, the functionality of two or more of the above units may be integrated into a single component.

If the number of taps of the Viterbi decoder 200 is L and the number of reduced-taps is K, the BMCU 210 performs 2^{K} branch metric calculations for a received symbol rₙ. A branch metric denotes a distance between codes in a branch corresponding to the received symbol rₙ. The branch metric calculation may be implemented to subtract a level from the received symbol rₙ and obtain an absolute value of the subtraction result or a square root of the absolute value as the branch metric.

The ACSU 220 determines a survivor path using the branch metric calculated by the BMCU 210 and a previously stored state metric. For example, the ACSU 220 obtains a new state metric by adding the branch metric calculated by the BMCU 210 to the previously stored state metric, selects a state metric having the smallest value from among obtained state metrics, and determines the selected state metric as the survivor path.

The PMU 230 stores and outputs the survivor path determined by the ACSU 220. An output signal of the PMU 230 can be defined as a decoded symbol of a survivor symbol. The PMU 230 may be implemented with a register exchange architecture for generating survivor symbols for respective states. The register exchange architecture transmits a survivor symbol to a multiplexer (MUX) and a register along the survivor path determined by the ACSU 220 and finally outputs a decoded symbol. The decoded symbol can be called a Viterbi decoded signal.

When the PMU 230 transmits a survivor symbol to the MUX and the register, the PMU 230 transmits at least one survivor symbol to the DFU 240. If the number of taps of the Viterbi decoder 200 is L and the number of reduced-taps is K, the PMU 230 provides (L−K) survivor symbols to the DFU 240, where L and K are positive integers and K is smaller than L.

If at least one survivor symbol is received from the PMU 230, the DFU 240 selects one of at least two levels based on the received survivor symbol and transmits the selected level to the BMCU 210. For example, if one survivor symbol is received from the PMU 230, the DFU 240 selects one of two levels and transmits the selected level to the BMCU 210. If two survivor symbols are received from the PMU 230, the DFU 240 selects one of four levels and transmits the selected level to the BMCU 210.

The number of levels selected by the DFU 240 is determined based on the number of taps of the Viterbi decoder 200. If the number of taps of the Viterbi decoder 200 is L, the DFU 240 has 2^{L} levels. If the levels are previously set, the most significant bit (MSB) of each level is a bit corresponding to received survivor symbols. For example, when one survivor symbol is received and L is 3, levels selected by the DFU 240 can be defined as 000, 100, 001, 101, 010, 110, 011, and 111, and the MSB of each level corresponds to the survivor symbol.

When the levels are previously set, the levels can be set by considering a case where level distribution of the received symbol rₙ has asymmetry. For example, when the received symbol rₙ has −1 and 1 and has asymmetry for 000, 001, 010, 011,100, 101, 110, and 111 in PR(1, 2, 1), levels are set to provide values corresponding to “−4, −2, 0, 2, −2, 0, 2, and 4”. However, when the asymmetry of the level distribution of the received symbol rₙ is considered in the conditions described above, the levels can be set to provide values corresponding to “−4, −2.2, −0.4,1, 8, −2.2, −0.4,1.8, and 4”. The BMCU 210 performs the branch metric calculation using the level transmitted from the DFU 240.

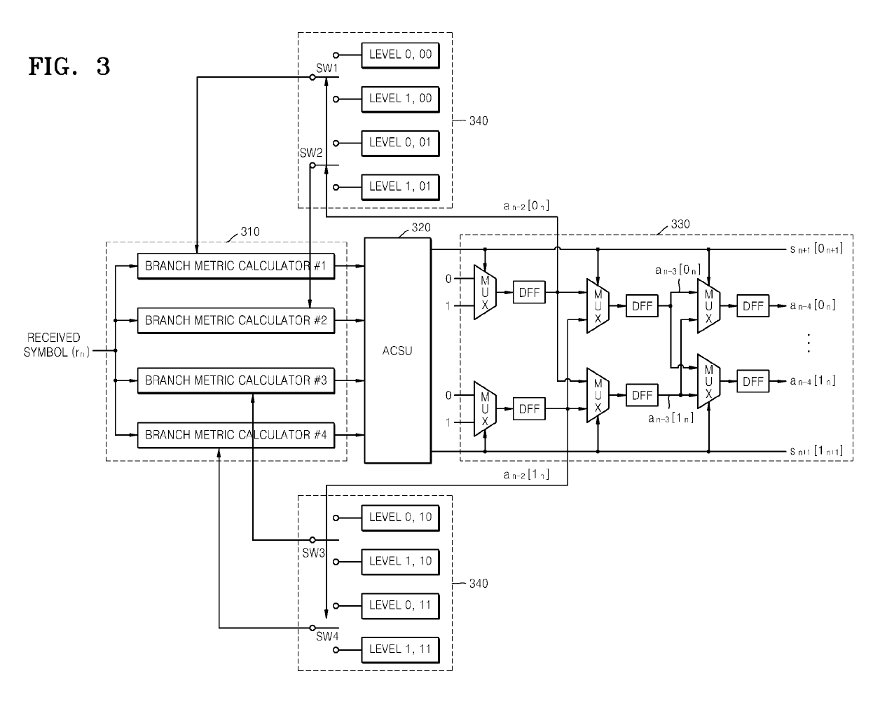

FIG. 3 is a detailed block diagram of the Viterbi decoder 200 shown in FIG. 2, according to an embodiment of the present invention, where the number L of taps of the Viterbi decoder 200 is 3 and the number K of reduced-taps is 2. Referring to FIG. 3, a BMCU 310 corresponds to the BMCU 210 shown in FIG. 2 and is configured to perform 2² (4) branch metric calculations (branch metric calculators #1˜#4) using a level transmitted from a DFU 340 and a received symbol rₙ.

A PMU 330 corresponds to the PMU 230 shown in FIG. 2 and transmits one survivor symbol (aₙ₋₂[0ₙ], aₙ₋₂[1ₙ]) to the DFU 340. The survivor symbol aₙ₋₂[0] is a survivor symbol corresponding to (n−2) hours from a survivor path in a state On. The survivor symbol aₙ₋₂[1ₙ] is a survivor symbol corresponding to (n−2) hours from a survivor path in a state 1ₙ. The PMU 330 is configured to include path memories corresponding to around five times the number K of reduced-taps; however, the PMU 330 according to other aspects of the present invention may include greater or fewer path memories.

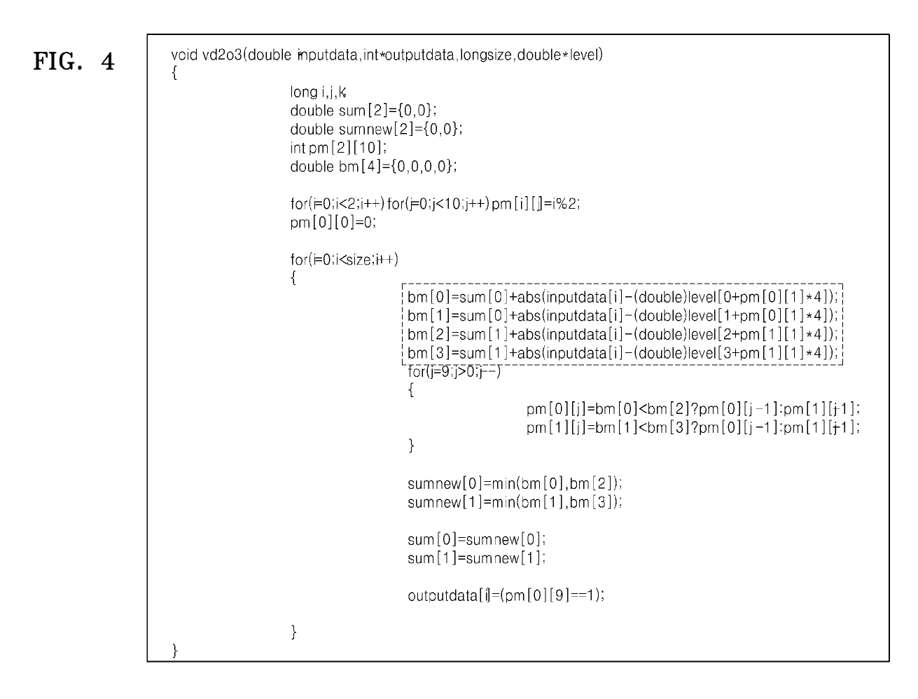

If the number of taps of the Viterbi decoder is L, the PMU 330 transmits survivor symbols from a survivor symbol a_{n-L-1} to the DFU 340. For example, when L=4 and K=3, the PMU 330 may determine survivor symbols aₙ₋₃[0ₙ] aₙ₋₃[1ₙ] aₙ₋₃[2ₙ] aₙ₋₃[3ₙ] and transmit the determined survivor symbols to the DFU 340. When this is represented in the C programming language, the dotted box of FIG. 4 can be defined as below.

bm[0]=sum[0]+abs(inputdata[i]−(double)level[0+pm[0][2]*8]);
bm[1]=sum[0]+abs(inputdata[i]−(double)level[1+pm[0][2]*8]);
bm[2]=sum[1]+abs(inputdata[i]−(double)level[2+pm[1][2]*8]);
bm[3]=sum[1]+abs(inputdata[i]−(double)level[3+pm[1][2]*8]);
bm[4]=sum[2]+abs(inputdata[i]−(double)level[4+pm[2][2]*8]);
bm[5]=sum[2]+abs(inputdata[i]−(double)level[5+pm[2][2]*8]);
bm[6]=sum[3]+abs(inputdata[i]−(double)level[6+pm[3][2]*8]);

FIG. 4 is a syntax obtained by representing the Viterbi decoder shown in FIG. 3 in the C programming language, according to an embodiment of the present invention. The Viterbi decoder may also be implemented in other programming languages, such as C++.

In addition, the PMU 330 has the register exchange architecture shown in FIG. 2. The PMU 330 has an architecture in which MUXs selecting and transmitting one of 0 and 1 along a survivor path transmitted from the ACSU 320 and D flip-flops (DFFs) storing signals output from the MUXs and outputting the stored values as survivor symbols are combined. Sₙ₊₁[0ₙ₊₁] is the determination of the ACSU 320 for two-path extension in a state 0ₙ₊₁ and corresponds to the survivor path described above. Sₙ₊₁[1ₙ₊₁] is a determination of the ACSU 320 for two-path extension in a state 1ₙ₊₁ and corresponds to the survivor path described above.

The DFU 340 corresponds to the DFU 240 shown in FIG. 2, where 8 levels are previously set and the MSB of each of the 8 levels is a bit corresponding to a fed-back survivor symbol. The DFU 340 has 8 previously set levels 000, 100, 001, 101, 010, 110, 011, and 111. If a survivor symbol aₙ₋₂[0] fed-back from the PMU 330 is 0, a switch SW1 selects 000 and transmits 000 to the branch metric calculation #1, and a switch SW2 selects 001 and transmits 001 to the branch metric calculation #2. However, if the survivor symbol aₙ₋₂[0ₙ] fed-back from the PMU 330 is 1, the switch SW1 selects 100 and transmits 100 to the branch metric calculation #1, and the switch SW2 selects 101 and transmits 101 to the branch metric calculation #2.

If a survivor symbol aₙ₋₂[1ₙ] fed-back from the PMU 330 is 0, a switch SW3 selects and transmits 010 to the branch metric calculation #3, and a switch SW4 selects 011 and transmits 011 to the branch metric calculation #4. However, if the survivor symbol aₙ₋₂[1ₙ] fed-back from the PMU 330 is 1, the switch SW3 selects 110 and transmits 110 to the branch metric calculation #3, and the switch SW2 selects 111 and transmits 111 to the branch metric calculation #4. The ACSU 320 corresponds to the ACSU 220 shown in FIG. 2 and may be configured and operates in a similar manner as the ACSU 220.

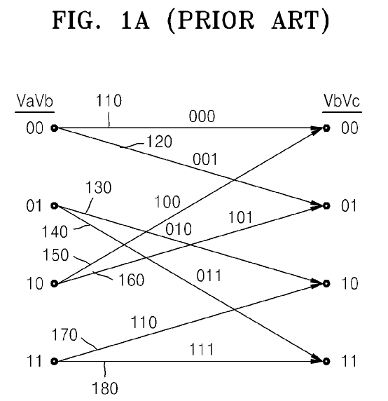

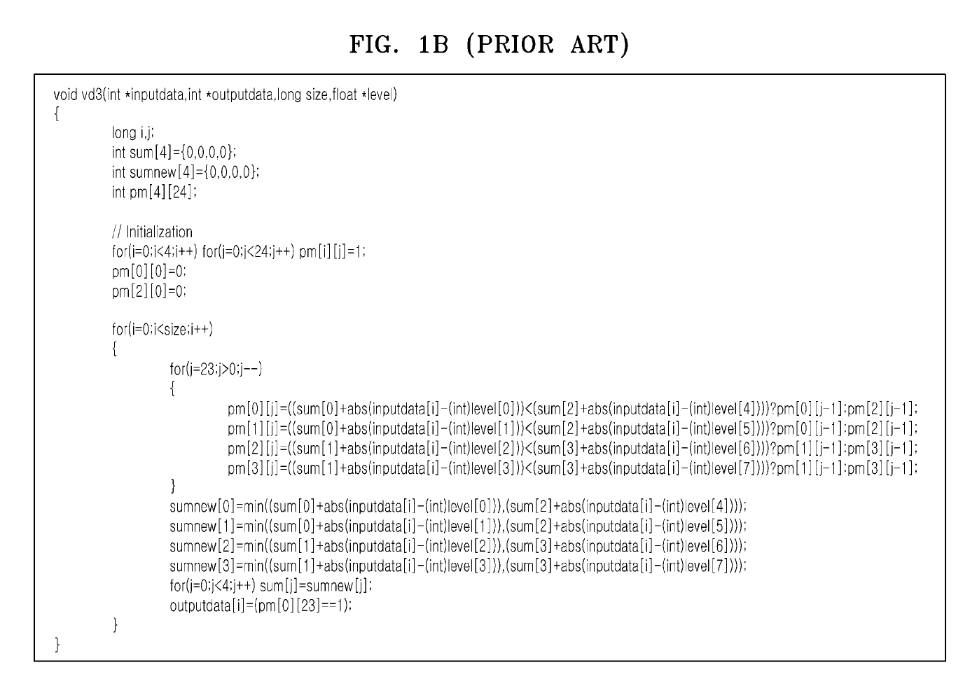

When FIG. 4 and FIG. 1B are compared to each other, the numbers of ‘sum’s and ‘sumnew’s are reduced in FIG. 4. In addition, for “bm[0], bm[1], bm[2], and bm[3]” corresponding to the branch metric calculators, four level items of ‘0’ to ‘3’ exist in FIG. 4, whereas 8 levels of ‘0’ to ‘7’ are all used in FIG. 1B. Thus, in the case of a 3-tap Viterbi decoder, 4 branch metric calculations are performed in FIG. 4, whereas 8 branch metric calculations are performed in FIG. 1B.

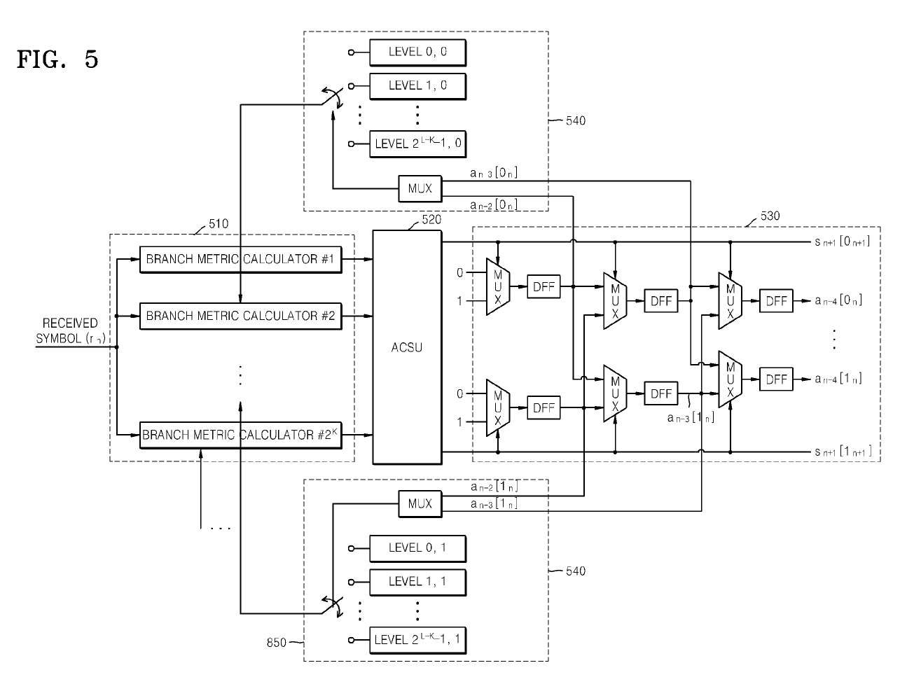

FIG. 5 is another detailed block diagram of the Viterbi decoder shown in FIG. 2, according to an embodiment of the present invention, where the difference between the number L of taps of a Viterbi decoder and the number K of reduced-taps is 2. As shown in FIG. 5, a BMCU 510 includes 2^{K} branch metric calculators #1˜#K and performs similar branch metric calculations as those in the BMCU 310 shown in FIG. 3.

An ACSU 520 and a PMU 530 are configured and operate in a similar manner as the ACSU 320 and the PMU 330 shown in FIG. 3, respectively. However, in FIG. 5, the PMU 530 transmits 2 (=L−K) survivor symbols aₙ₋₂[0], aₙ₋₃[0], aₙ₋₂[1ₙ], and aₙ₋₃[1] and aₙ₋₃[1ₙ] to a DFU 540.

The DFU 540 includes a MUX selecting and transmitting one of previously set 2^{L-K} levels (0, 0˜2^{L-k}−1, 0) according to 2^{L} levels and survivor symbols aₙ₋₂[0ₙ] and aₙ₋₃[0ₙ] to the BMCU 510 and a MUX selecting and transmitting one of previously set lower 2^{L-K} levels (0, 0˜2^{L-k}−1, 0) according to survivor symbols aₙ₋₂[1ₙ] and aₙ₋₃[1ₙ] to the BMCU 510.

As described above, when the difference between L and K is 2, the MUXs select one of 4 levels according to an input survivor symbol and transmits the selected level to the BMCU 510. For example, when the survivor symbols aₙ₋₂[0ₙ] and aₙ₋₃[0ₙ] are 00, the MUX selects a level (0, 0) and transmits the selected level (0, 0) to the MCU 510, and if the survivor symbols aₙ₋₂[1ₙ] and aₙ₋₃[1ₙ] are 11, the MUX selects a level (₂^{L-k}−1, 1) and transmits the selected level (2^{L-k}−1, 1) to the BMCU 510.

The number of survivor symbols fed-back from the PMU 530 is determined according to the difference (L−K) between the number L of taps of the Viterbi decoder and the number K of reduced-taps. An architecture of the DFU 540 is determined according to the number of fed-back survivor symbols. The number of levels set in the DFU 540 is determined according to the number L of taps of the Viterbi decoder. The BMCU 510 is determined according to the number K of reduced-taps. The number of path memories included in the PMU 530 can be around 5 times the number K of reduced-taps.

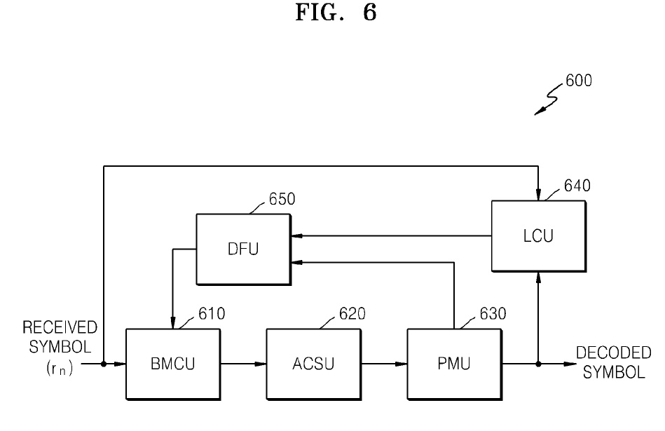

FIG. 6 shows a Viterbi decoder 600 according to another embodiment of the present invention. The Viterbi decoder 600 includes a BMCU 610, an ACSU 620, a PMU 630, a level calculation unit (LCU) 640, and a DFU 650.

The Viterbi decoder 600 shown in FIG. 6 is configured and operates in a similar manner as the Viterbi decoder 200 shown in FIG. 2, with the exception of the calculating and setting levels included in the DFU 650. Thus, the BMCU 610, the ACSU 620, the PMU 630, and the DFU 650 shown in FIG. 6 are configured and operate similarly to the BMCU 210, the ACSU 220, the PMU 230, and the DFU 240 shown in FIG. 2, respectively.

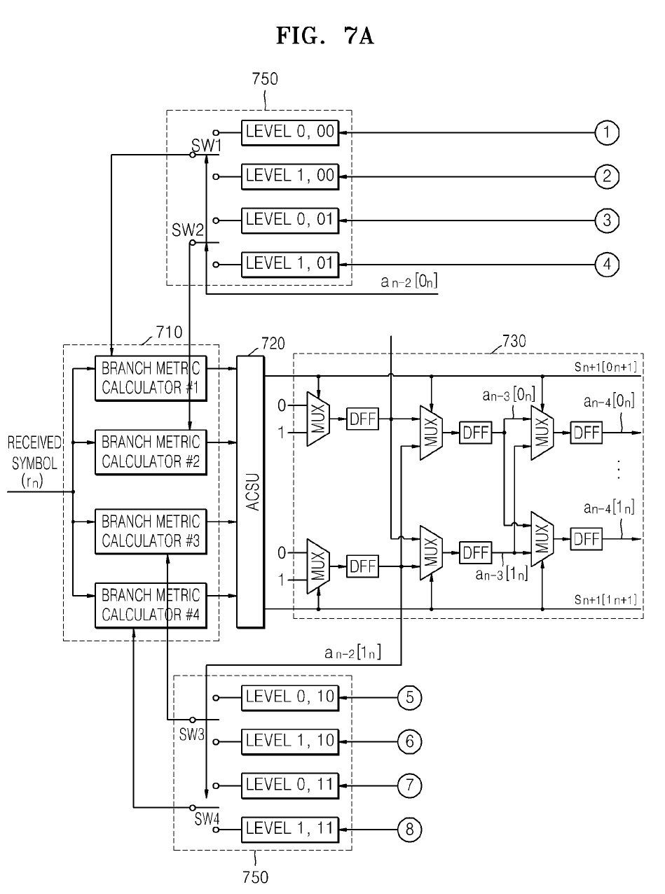

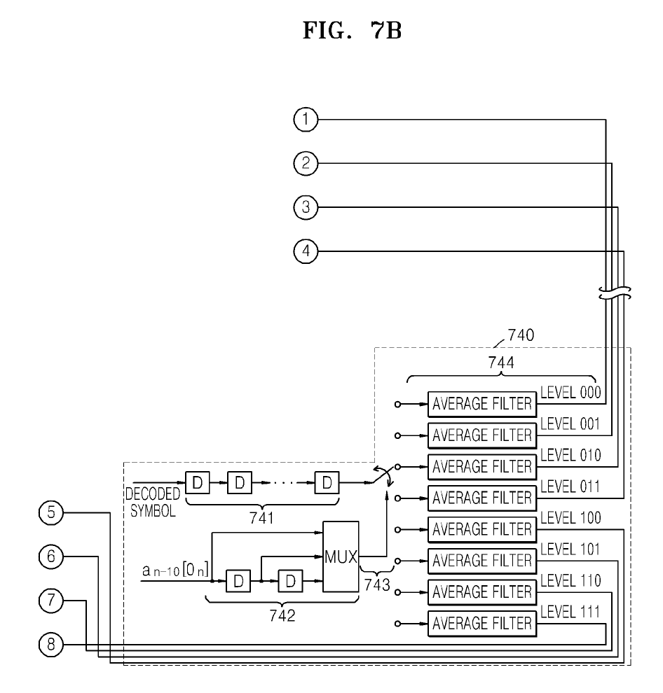

The LCU 640 calculates a level using a decoded symbol output from the PMU 630 and a received symbol input from the BMCU 610. However, the LCU 640 may be implemented to calculate the level using binary data received from the outside and the received symbol. If the Viterbi decoder 600 is implemented as shown in FIGS. 7A and 7B, the LCU 640 may be configured in a similar manner as an LCU 740 shown in FIG. 7B.

FIGS. 7A and 7B are a detailed block diagram of the Viterbi decoder 600, according to another embodiment of the present invention, where the number L of taps of the Viterbi decoder 600 is 3 and the number K of reduced-taps is 2. The LCU 740 includes a delay unit 741, a selection signal generator 742, a selector 743, and a level value generator 744.

The delay unit 741 includes a plurality of delayers D and delays a received symbol. The number of delayers D included in the delay unit 741 depends on the number of path memories included in a PMU 730 and a time taken for the selection signal generator 742 to generate a selection signal.

The selection signal generator 742 generates the selection signal by including a plurality of delayers D delaying a decoded symbol aₙ₋₁₀[0ₙ] and a MUX generating the selection signal from signals output from the plurality of delayers D. Since the Viterbi decoder 600 as shown in FIG. 7B needs 8 levels, the selection signal generated by the MUX has 3 bits.

The LCU 740 includes 8 average filters, each average filter generating a level value. If a received symbol delayed according to the selection signal is input, each of the average filters obtains an average value of the input received symbol for a predetermined period and outputs the obtained average value as a level value. Each average filter can include a low pass filter (LPF). The output level value is transmitted to a DFU 750.

A BMCU 710, an ACSU 720, a PMU 730, and the DFU 750 shown in FIGS. 7A and 7B are configured and operate similarly to the BMCU 310, the ACSU 320, the PMU 330, and the DFU 340 shown in FIG. 3, respectively. The PMU 730 has path memories of which a horizontal length is 10, where the horizontal length is around 5 times a channel characteristic (or 5 times the number K of reduced-taps). However, even if the horizontal length is set shorter or longer than 5 times the channel characteristic, the performance of the Viterbi decoder is not affected. If the horizontal length is changed, the number of delayers included in the LCU 740 may also need to be changed.

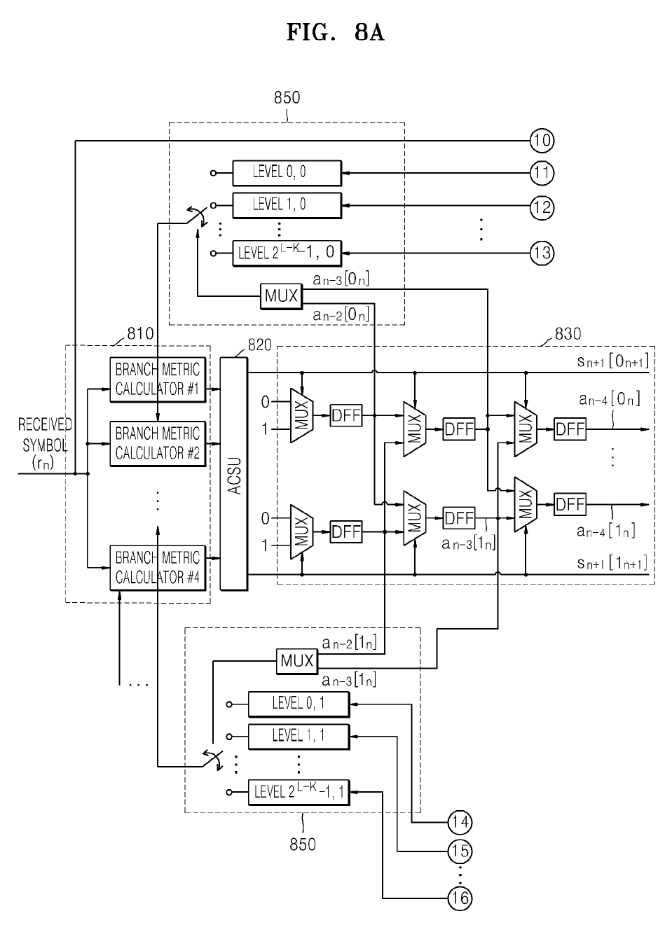

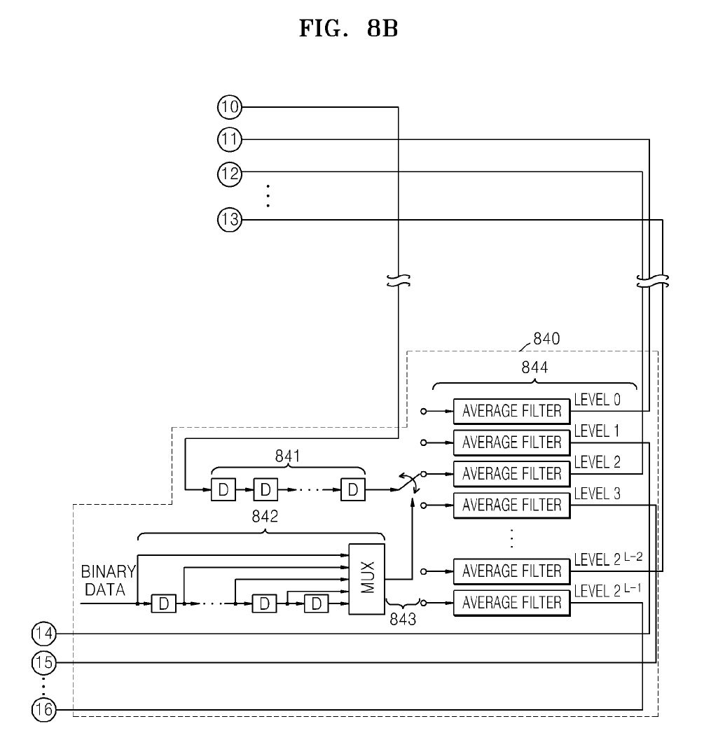

FIGS. 8A and 8B are another detailed block diagram of the Viterbi decoder 600, according to another embodiment of the present invention, where the difference between the number L of taps of the Viterbi decoder 600 and the number K of reduced-taps is 2 as shown in FIG. 5. Thus, a UMCU 810, an ACSU 820, a PMU 830, and a UFU 850 shown in FIGS. 8A and 8B are configured and operate similarly to the BMCU 510, the ACSU 520, the PMU 530, and the DFU 540 shown in FIG. 5, respectively.

Like the LCU 740, an LCU 840 includes a delay unit 841, a selection signal generator 842, a selector 843, and a level value generator 844. However, since the number of levels needed in FIGS. 8A and 8B is 2^{L}, the number of delayers D included in the delay unit 841, the number of delayers D included in the selection signal generator 842, and the number of average filters included in the level value generator 844 are set to generate the 2^{L} levels.

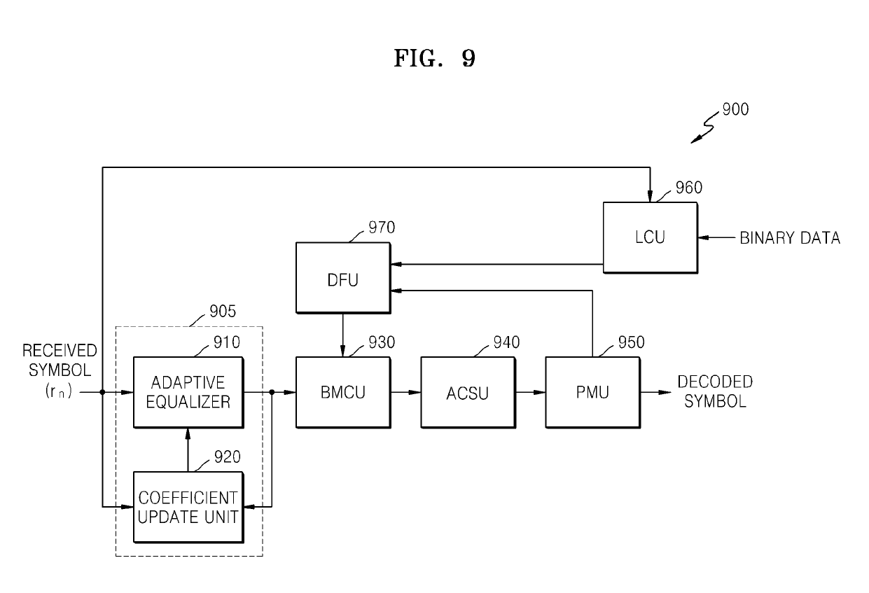

FIG. 9 is a functional block diagram of a Viterbi decoder 900 according to another embodiment of the present invention, where an adaptive equalization unit (AEU) 905 is further included in the embodiment of FIG. 6. However, the AEU 905 may also be incorporated into a Viterbi decoder according to other aspects of the present invention, such as the Viterbi decoders shown in FIGS. 2, 7A, 7B, 8A, and 8B. The AEU 905 cancels noise from a received symbol and includes an adaptive equalizer 910 and a coefficient update unit 920.

The adaptive equalizer 910 equalizes the received symbol to cancel noise from the received symbol. For this purpose, the adaptive equalizer 910 may be configured with a finite impulse response (FIR) filter. The coefficient update unit 920 updates a coefficient of the adaptive equalizer 910 using an input signal of the adaptive equalizer 910 and an output signal of the adaptive equalizer 910.

An LCU 960 receives an input signal of the AEU 905 as the received symbol, calculates 2^{L} levels using input binary data as shown in FIGS. 8A and 8B, and transmits the calculated 2^{L} levels to a DFU 970. A BMCU 930, an ACSU 940, a PMU 950, and the DFU 970 shown in FIG. 9 may be configured and operate similarly to the BMCU 810, the ACSU 820, the PMU 830, and the DFU 850 shown in FIG. 8A, respectively.

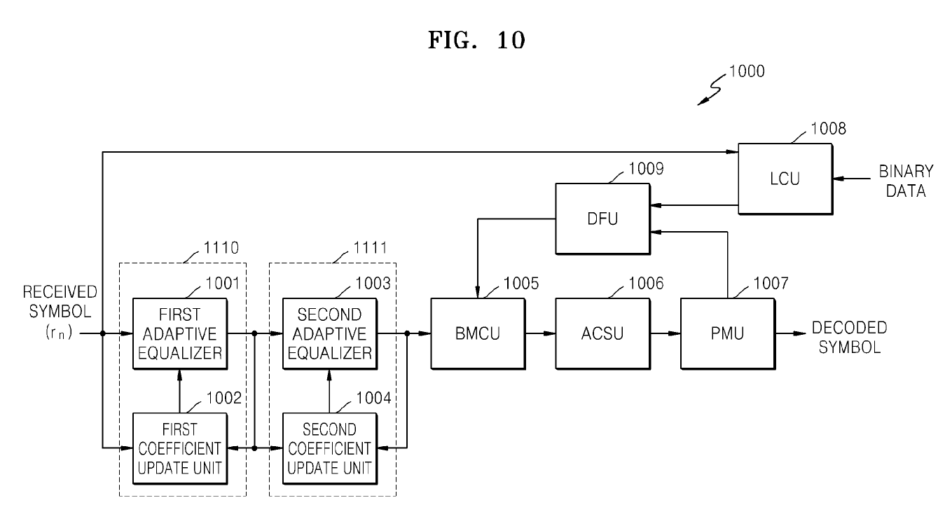

FIG. 10 is a functional block diagram of a Viterbi decoder 1000 according to another embodiment of the present invention, where a first adaptive equalization unit (AEU) 1110 and a second AEU 1111 are further included in the embodiment of FIG. 6. The first AEU 1110 equalizes a received symbol to compensate for a frequency gain characteristic of the received symbol and includes a first adaptive equalizer 1001 and a first coefficient update unit 1002. The first adaptive equalizer 1001 improves the frequency gain characteristic of the received symbol by changing the amplitude of the received symbol according to a coefficient varying according to a predetermined level (or a target level). For this purpose, the first adaptive equalizer 1001 may be configured with an FIR filter. The predetermined level can be determined based on a result obtained from a performance comparison result performed by searching for conditions in which a modulation transfer function (MTF) can be experimentally changed. The first coefficient update unit 1002 updates a coefficient of the first adaptive equalizer 1001 using an input signal of the first adaptive equalizer 1001 and an output signal of the first adaptive equalizer 1001.

The second AEU 1111 includes a second adaptive equalizer 1003 and a second coefficient update unit 1004 in order to cancel noise from a signal output from the first AEU 1110. The second adaptive equalizer 1003 equalizes a signal output from the first adaptive equalizer 1001 to cancel noise from the signal output from the first AEU 1110. For this purpose, like the first adaptive equalizer 1001, the second adaptive equalizer 1003 may be configured with an FIR filter. The second coefficient update unit 1004 updates a coefficient of the second adaptive equalizer 1003 using an input signal of the second adaptive equalizer 1003 and an output signal of the second adaptive equalizer 1003.

An LCU 1008 receives an input signal of the first AEU 1110 as the received symbol and calculates 2^{L} levels using binary data input from the outside as shown in the LCU 840 of FIG. 8B. A BMCU 1005, an ACSU 1006, a PMU 1007, and a DFU 1009 shown in FIG. 10 may be configured and operate similarly to the BMCU 810, the ACSU 820, the PMU 830, and the DFU 850 shown in FIG. 8A, respectively.

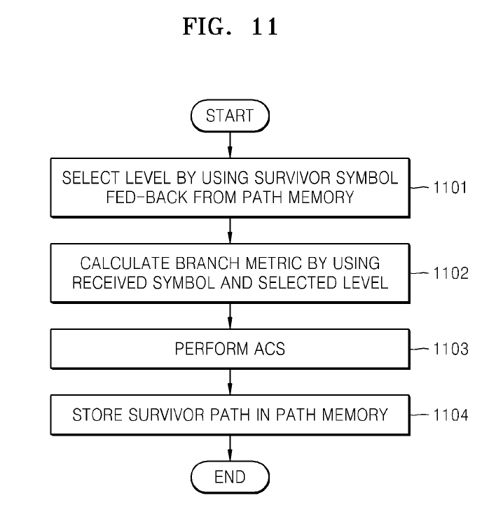

FIG. 11 is a flowchart of a Viterbi decoding method according to an embodiment of the present invention. In operation 1101, at least two levels are selected based on one survivor symbol fed back from a path memory. In this case, the levels may be previously set as shown in FIG. 2 or calculated and set as shown in one of the embodiments of FIGS. 6 through 9. If the levels are previously set, a level considering a case where level distribution of a received symbol is asymmetric may be included. If the number of taps of a Viterbi decoder is L and the number of reduced-taps is K, the number of fed-back survivor symbols is L−K, and the number of at least two levels is 2^{L}. L and K may be positive integers, and K may be smaller than L.

In operation 1102, a branch metric is calculated using the received symbol and the selected level. If the number of reduced-taps is K, 2^{K} branch metric calculations are performed. In operation 1103, a survivor path is determined using the calculated branch metric and a previously stored state metric. In operation 1104, the determined survivor path is stored in the path memory.

Aspects of the present invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CDs, DVDs, magnetic tapes, floppy disks, and optical data storage devices. The computer readable recording medium can also be distributed over network coupled computer systems so that the computer readable code is stored and executed in a distributed fashion.

As described above, according to aspects of the present invention, by selecting and providing a level used for branch metric calculation by using a survivor symbol fed-back from a path memory unit, the number of branch metric calculators can be reduced, thereby simplifying hardware of a Viterbi decoder. In addition, by previously setting a level used for branch metric calculation, even if level distribution of a received symbol is asymmetric, an optimal level can be provided, thereby obtaining an optimal Viterbi decoding result. Furthermore, by calculating a level to be used for branch metric calculation by using one of a decoded symbol output from the path memory unit and of binary data input from the outside, and a received symbol of the Viterbi decoder, even if an amplitude of the received symbol shakes or is asymmetric, an optimal level can be used, thereby improving the performance of the Viterbi decoder.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A Viterbi decoder comprising:
a path memory unit (PMU) to store a survivor path;
a decision feedback unit (DFU) to select one of at least two levels based on at least one survivor symbol fed back from the PMU;
a branch metric calculation unit (BMCU) to calculate a branch metric based on the level selected by the DFU and the received symbol; and
an add-compare-selection unit (ACSU) to determine the survivor path based on the branch metric calculated by the BMCU and a previously stored state metric and to transmit the determined survivor path to the PMU.

2. The Viterbi decoder of claim 1, wherein a number of taps of the Viterbi decoder is L and a number of reduced-taps is K, the number of fed-back survivor symbols is L−K, the DFU comprises 2^{L} levels, L and K are positive integers, and K is smaller than L.

3. The Viterbi decoder of claim 2, wherein the BMCU performs 2^{K} branch metric calculations.

4. The Viterbi decoder of claim 3, wherein the at least two levels are previously set levels.

5. The Viterbi decoder of claim 4, wherein the previously set levels comprise a level based on a case where level distribution of the received symbol has asymmetry.

6. The Viterbi decoder of claim 5, wherein the most significant bit (MSB) of each of the at least two levels is a bit corresponding to the fed-back survivor symbol.

7. The Viterbi decoder of claim 3, further comprising a level calculation unit (LCU) to calculate the at least two levels and to transmit the calculated level to the DFU.

8. The Viterbi decoder of claim 7, wherein the LCU calculates the levels based on the received symbol and a decoded symbol output from the PMU and transmits the calculated levels to the DFU.

9. The Viterbi decoder of claim 8, further comprising:
an adaptive equalization unit (AEU) to equalize the received symbol in order to cancel noise from the received symbol and to transmit the equalized symbol to the BMCU;
wherein the received symbol of the LCU is an input signal of the AEU.

10. The Viterbi decoder of claim 8, further comprising:
a first adaptive equalization unit (AEU) to equalize the received symbol in order to compensate for a frequency characteristic of the received symbol; and
a second AEU to equalize an output signal of the first AEU in order to cancel noise from the output signal of the first AEU and to transmit the equalized symbol to the BMCU;
wherein the received symbol of the LCU is an input signal of the first AEU.

11. The Viterbi decoder of claim 7, wherein the LCU calculates the levels based on the received symbol and binary data input from outside and transmits the calculated levels to the DFU.

12. The Viterbi decoder of claim 11, further comprising:
an adaptive equalization unit (AEU) to equalize the received symbol in order to cancel noise from the received symbol and transmitting the equalized symbol to the BMCU;
wherein the received symbol of the LCU is an input signal of the AEU.

13. The Viterbi decoder of claim 11, further comprising:
a first adaptive equalization unit (AEU) to equalize the received symbol in order to compensate for a frequency characteristic of the received symbol; and
a second AEU to equalize an output signal of the first AEU in order to cancel noise from the output signal of the first AEU and to transmit the equalized symbol to the BMCU;
wherein the received symbol of the LCU is an input signal of the first AEU.

14. A Viterbi decoding method comprising:
selecting at least two levels based on at least one survivor symbol fed back from a path memory;
calculating a branch metric based on the selected levels and a received symbol;
determining a survivor path based on the calculated branch metric and a previously stored state metric; and
storing the determined survivor path.

15. The Viterbi decoding method of claim 14, wherein a number of taps of a Viterbi decoder is L and a number of reduced-taps is K, the number of fed-back survivor symbols is L−K, the at least two levels are 2^{L} levels, L and K are positive integers, and K is smaller than L.

16. The Viterbi decoding method of claim 15, wherein the number of reduced-taps is K and the calculating of the branch metric comprises performing 2^{K} branch metric calculations.

17. The Viterbi decoding method of claim 16, wherein the at least two levels are previously set levels.

18. The Viterbi decoding method of claim 17, wherein the previously set levels comprise a level based on a case where level distribution of the received symbol has asymmetry.

19. The Viterbi decoding method of claim 16, wherein the at least two levels are calculated using the received symbol and a decoded symbol obtained by performing the Viterbi decoding.

20. The method of claim 19, wherein the at least two levels are calculated using the received symbol and binary data input from the outside.

21. A computer readable medium comprising instructions that, when read by a computer, cause the computer to perform the method of claim 14.

22. A Viterbi decoder comprising:
a path memory unit (PMU) to store a survivor path and to output at least one survivor symbol based on the survivor path;
a decision feedback unit (DFU) to receive the at least one survivor symbol from the PMU and to select one of L levels based on the at least one survivor symbol, where L is at least two;
a branch metric calculation unit (BMCU) to calculate a branch metric based on an input symbol, the level selected by the DFU, and a number of reduced taps K, where K is smaller than L; and
an add-select-compare unit (ASCU) to determine the survivor path based on the branch metric calculated by the BMCU and a previously stored state metric and to transmit the survivor path to the PMU to be stored;
wherein the PMU outputs a number of survivor symbols equal to L−K.

23. The Viterbi decoder of claim 22, further comprising:
a level calculation unit (LCU) to calculate a level based the at least one survivor symbol and the input symbol and to transmit the calculated level to the DFU;
wherein the DFU selects the level based on the calculated level received from the LCU.

24. The Viterbi decoder of claim 23, wherein the LCU comprises:
a delay unit to delay the input signal;
a selection signal generator to generate a selection signal;
a level value generator to generate a plurality of levels; and
a selector to select one of the generated levels as the calculated level based on the delayed input signal and the selection signal;
wherein the delay unit comprises a plurality of delayers to delay the input signal, the number of delayers determined based on a number of path memories included in the PMU and a time taken by the selection signal generator to generate the selection signal.

25. The Viterbi detector of claim 24, wherein:
the level value generator comprises 2^{L} average filters, each average filter generating one of the plurality of levels.

26. The Viterbi detector of claim 22, further comprising:
an adaptive equalization unit (AEU) to cancel noise from the received symbol and to transmit the noise-cancelled received symbol to the BMCU;

27. The Viterbi detector of claim 22, further comprising:
a first AEU to cancel noise from the received symbol; and
a second AEU to compensate for a frequency gain characteristic of the noise-cancelled received symbol and to transmit the compensated received symbol to the BMCU.
